(19) United States
(12) Patent Application Publication
(10) Pub. No.: US 2017/0242462 A1
(43) Pub. Date: Aug. 24, 2017

(54) ELECTRONIC APPARATUS

(71) Applicants: KABUSHIKI KAISHA TOSHIBA, Tokyo (JP); Toshiba Client Solutions CO., LTD., Tokyo (JP)

(72) Inventor: Nobuto Fujiwara, Hino Tokyo (JP)

(21) Appl. No.: 15/441,155

(22) Filed: Feb. 23, 2017

Related U.S. Application Data
(60) Provisional application No. 62/299,505, filed on Feb. 24, 2016.

(51) Int. Cl. G06F 1/20; H05K 7/20; G06F 1/16

(52) U.S. Cl. CPC G06F 1/203; G06F 1/1656; H05K 7/20336; H05K 7/20181

(57) ABSTRACT

According to one embodiment, an electronic apparatus includes a housing having an internal space, a fan provided inside the housing, a ventilation flue provided inside the housing to circulate air in the internal space, the air emitted from the fan and to guide the air to a suction opening of the fan, and a heat generator provided in a path of a flow of the air.

### CROSS-REFERENCE TO RELATED APPLICATIONS

This application claims the benefit of U.S. Provisional Application No. 62/299,505, filed Feb. 24, 2016, the entire contents of which are incorporated herein by reference.

### FIELD

Embodiments described herein relate generally to an electronic apparatus comprising a built-in fan.

### BACKGROUND

It is necessary to cool the electronic components provided inside computers such that the preset temperature is not exceeded. A radiating plate or fan is a known mechanism for cooling the electronic components. However, if the attachment area of the radiating plate is great, the cost and weight are increased. When a fan is used, noise may be generated around an inlet or an outlet, or the operation noise of the fan may be released from the outlet, etc.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective illustration showing a personal computer according to one embodiment.

FIG. 2 is a plan view showing a main portion of a personal computer according to a first embodiment.

FIG. 3 is a cross-sectional view showing the main portion.

FIG. 4 is a perspective illustration showing the main portion.

### DETAILED DESCRIPTION

Various embodiments will be described hereinafter with reference to the accompanying drawings.

In general, according to one embodiment, an electronic apparatus is a personal computer comprising a built-in fan.

### First Embodiment

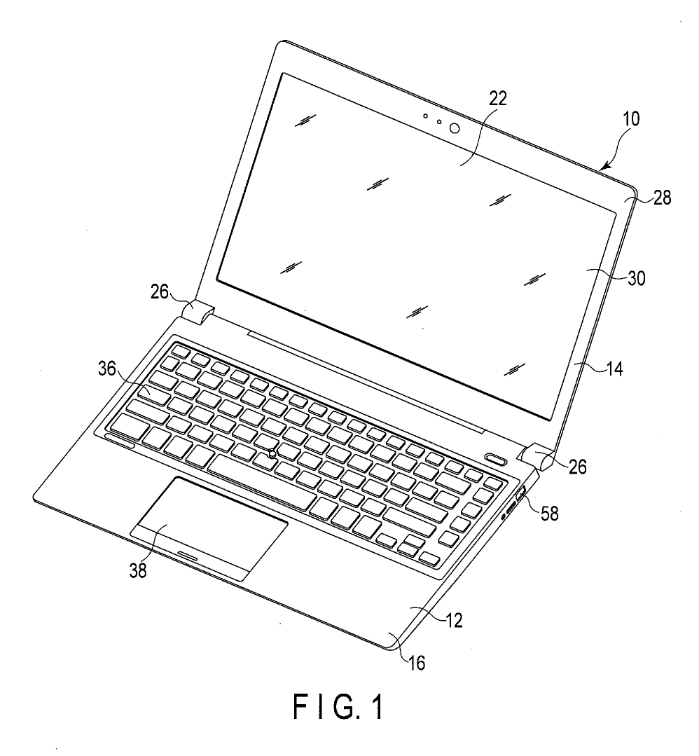

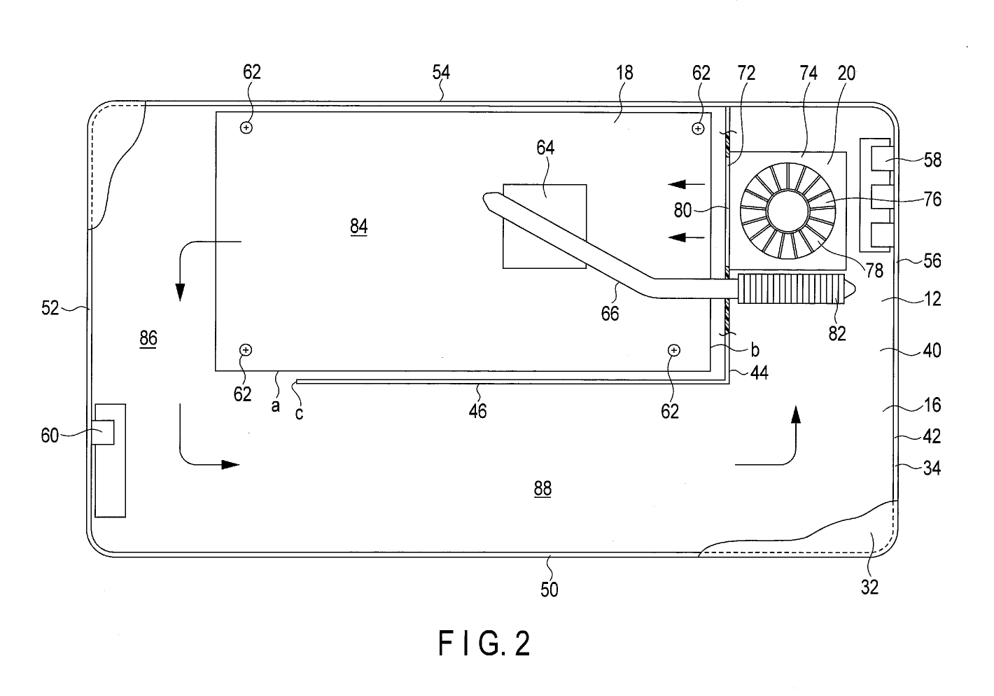

FIG. 1 shows a computer 10 according to the present embodiment. FIG. 1 is a perspective illustration showing the computer 10 obliquely from above. The computer 10 is a clamshell personal computer, and comprises a main portion 12 and a display portion 14 rotatably attached to the main portion 12. A fan 20 (see FIG. 2) is provided in the main portion 12. A display screen 22 is provided in the display portion 14.

In the following description, the upper and lower sides and the front and rear sides of the computer 10 are determined as follows. When the main portion 12 is placed on a horizontal table, the direction of gravity is defined as the downward direction of the computer 10, and the opposite direction is defined as the upward direction. When the display screen 22 of the display portion 14 faces the user, the user side is defined as the forward or front side of the computer 10, and the opposite side is defined as the backward or rear side. Based on this definition, the right and left of the computer 10 are determined. For the sake of convenience, the computer 10 may be explained using different terms.

The main portion 12 comprises a substrate 18, the fan 20 (see FIG. 2 for the substrate 18 and the fan 20), a power source portion, etc., inside a housing 16 in the outer circumference. The display portion 14 is rotatably attached to the main portion 12 by a hinge 26. They are connected via a flexible cable, etc. The display portion 14 may be removably attached to the main portion 12.

The display portion 14 comprises a liquid crystal panel 30 inside a display portion housing 28 as shown in FIG. 1. The display portion housing 28 is formed of synthetic resin or metal, etc. The front side of the display portion housing 28 is open.

The liquid crystal panel 30 forms an image by arbitrarily driving the liquid crystal with a liquid crystal driving circuit and controlling the passage of light. A backlight is provided on the rear surface of the liquid crystal panel 30. The backlight is, for example, a lighting device comprising an LED as a light source, and uniformly irradiates the liquid crystal panel 30 with light from the rear side. In the display portion 14, the liquid crystal panel 30 is exposed from the opening portion provided in the display portion housing 28. Thus, the display screen 22 is formed on the front side.

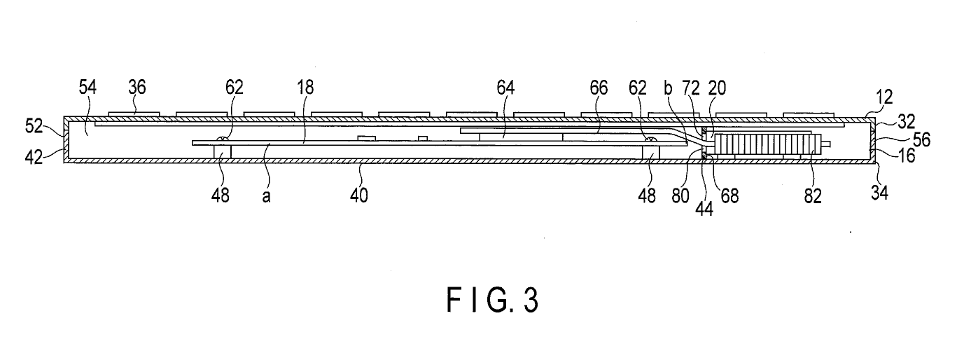

As shown in FIG. 2 and FIG. 3, the main portion 12 comprises the substrate 18, the fan 20 and the power source portion inside the housing 16. FIG. 2 is a planar cross-sectional view showing the inner side by cutting the main portion 12. FIG. 3 is a side cross-sectional view showing the inner side by cutting the main portion 12.

The housing 16 is substantially rectangular in a planar view. The housing 16 is formed by integrally combining upper and lower plates 32 and 34 formed of synthetic resin up and down. In the housing 16, a space shielded from outside is defined by combining the upper and lower plates 32 and 34.

As input devices, a keyboard unit 36 and a touchpanel 38 (see FIG. 1) are provided on the upper plate 32. The lower plate 34 comprises a bottom plate 40, a sidewall 42 provided upright on the edge of the bottom plate 40, a first partition wall 44, and a second partition wall 46.

The bottom wall 40 is flat, and has a predetermined strength. An attachment base 48 (see FIG. 3) is provided on the bottom plate 40. The attachment base 48 has a predetermined height from the bottom plate 40. The substrate 18 is attached to the upper surface of the attachment base 48.

The sidewall 42 comprises a first side plate 50, a second side plate 52, a third side plate 54 and a fourth side plate 56. These side plates are provided in the circumference of the bottom plate 40. Various attachment holes are formed on the sidewall 42. A socket 58, a card slot, a switch 60, etc., are attached to the attachment holes formed on the sidewall 42.

The material of the housing 16 is not limited to synthetic resin, and may be metal such as magnesium. The material of the upper plate 32 may not be the same as that of the lower plate 34. Only one of the upper and lower plates 32 and 34 may be formed of metal such as magnesium. The inside of the housing 16 may not be strictly airtight. The internal space of the housing 16 may be substantially shielded from outside. For example, an opening hole may be provided on the lower plate 34. For example, a gap may be provided around the attachment hole for attaching the socket 58. In this manner, the inside of the housing 16 may reasonably communicate with the outside.

The substrate 18 is secured to the upper surface of the attachment base 48 via a screw 62. Various electronic components including a CPU 64 as a heat generator are mounted on the substrate 18. The substrate 18 is secured to a position which is a predetermined height away from the bottom plate 40 by the attachment base 48. An appropriate gap is defined between the substrate 18 and the upper plate 32. An end of a heat pipe 66 as a heat conductive member is firmly attached to the upper surface of the CPU 64. The first partition wall 44 and the second partition wall 46 are provided laterally on the substrate 18.

The first partition wall 44 has a width in the upward and downward directions such that the upper end is in contact with the upper plate 32, and the lower end is in contact with the bottom plate 40. The first partition wall 44 is provided along a left border (b) (in a planar view, the right end) of the substrate 18 from the third side plate 54 of the lower plate 34 to a position beyond a front border (a) of the substrate 18. An opening portion 72 which penetrates the top and reverse sides of the first partition wall 44 is formed on the first partition wall 44 at a position corresponding to the fan 20. The second partition wall 46 is provided at the front end of the first partition wall 44.

The second partition wall 46 intersects the first partition wall 44 at substantially a right angle, and extends along the front border (a) of the substrate 18 in the direction of the second side plate 52 on the right side of the housing 16. A right end (c) (in the figure, the left end) of the second partition wall 46 is a predetermined distance away from the second side plate 52 toward the fan 20. A sufficient gap is defined between the right end (c) of the second partition wall 46 and the second side plate 52 such that air smoothly flows through the gap. In a manner similar to that of the first partition wall 44, the upper end of the second partition wall 46 is in contact with the upper plate 32, and the lower end of the second partition wall 46 is in contact with the bottom plate 40.

The fan 20 is a centrifugal fan comprising an outer frame element 74, blades 76 and a drive motor. The outer frame element 74 is flat and rectangular. The blades 76 are rotatably attached to the inside of the outer frame element 74. The blades 76 are attached to the drive shaft of the drive motor, and rotate inside the outer frame element 74 when the drive motor operates.

The fan 20 comprises a suction opening 78 on each of the upper and lower surfaces of the outer frame element 74, and a blast opening 80 on a side surface of the outer frame element 74. The fan 20 is secured in the following manner: the blast opening 80 conforms to the opening portion 72 and faces the left border (b) of the substrate 18; and the left border (b) is positioned at substantially the center of the blast opening 80 in the vertical direction. The fan 20 is secured such that a certain space is defined between the fan 20 and the bottom plate 40. Moreover, the housing 16 basically does not comprise an opening portion which connects the inside and outside of the housing 16 near the suction opening 64 of the fan 20.

The CPU 64 is provided at a position to which air is emitted from the blast opening 80 of the fan 20. The other end of the heat pipe 66 attached to the CPU 64 penetrates the first partition wall 44, and extends laterally to the suction opening 78 of the fan 20. A plurality of fins 82 are provided at the other end of the heat pipe 66 lateral to the suction opening 78.

A first ventilation flue 84, a second ventilation flue 86 and a third ventilation flue 88 are formed in the internal space of the housing 16 by the first partition wall 44 and the second partition wall 46. The first ventilation flue 84 ranges from the first partition wall 44 to the right end (c) (in a planar view, the left end) of the second partition wall 46.

The second ventilation flue 86 is continuous with the first ventilation flue 84, and ranges from the right end (c) of the second partition wall 46 to the second side plate 52. The third ventilation flue 88 is continuous with the second ventilation flue 86, and ranges from the right end (c) of the second partition wall 46 to the fan 20. The first to third ventilation flues 84, 86 and 88 are provided on the top and reverse sides of the substrate 18 in substantially the same manner.

A temperature sensor is provided near the CPU 64. The temperature sensor detects the temperature around the CPU 64, and transmits the detected value to a control device. The temperature sensor may be provided in the CPU 64.

The control device compares the detected value transmitted from the temperature sensor with a threshold. When the control device determines that the detected value transmitted from the temperature sensor exceeds the threshold, the control device issues an instruction for driving the fan 20. The threshold is set such that the CPU 64 must be forcibly cooled when the detected value exceeds the threshold.

Now, this specification explains the operation and effect of the computer 10. When the computer 10 is switched on, and the computer 10 is used by the user, heat is generated in the CPU 64 and other electronic components. The heat generated in the CPU 64, etc., increases the temperature of electronic components such as the CPU 64 and the surrounding temperature. The temperature sensor detects the temperature, and transmits the detected value to the control device.

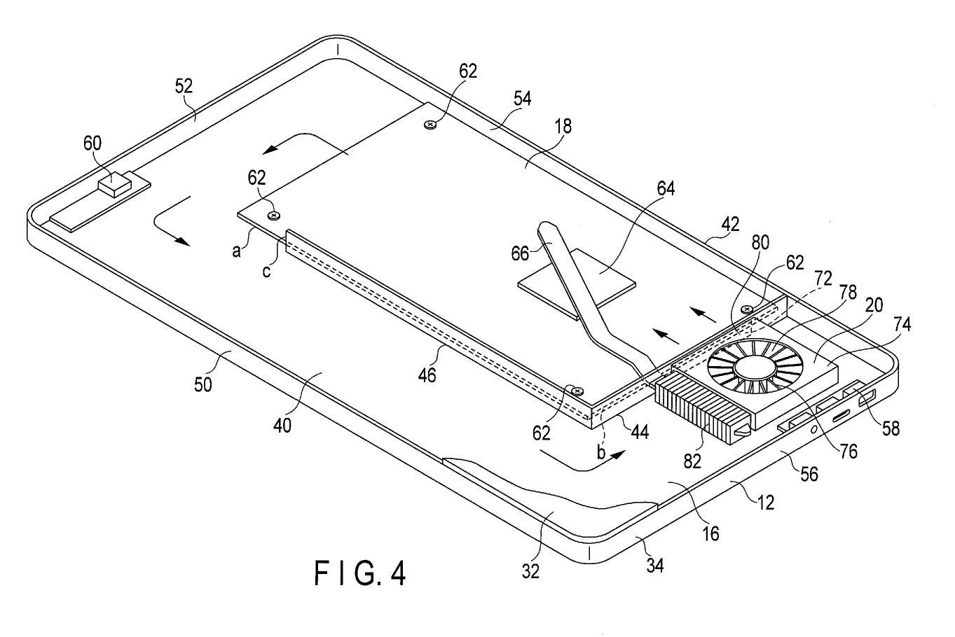

The control device compares the value detected by the temperature sensor with a threshold. When the control device determines that the detected value exceeds the threshold, the control device issues an instruction for driving the fan 20. When an operation signal is output from the control device, the fan 20 drives the drive motor and rotates the blades 62. In connection with the rotation, air is sucked from the suction opening 78 and emitted from the blast opening 80. In FIG. 2 and FIG. 4, the flow of air emitted from the blast opening 80 is shown with arrows.

The suction opening 78 is open inside the third ventilation flue 88. Thus, the fan 20 sucks air from the third ventilation flue 88 through the fins 82 of the heat pipe 66. The blast opening 80 faces the left border (b) of the substrate 18 via the opening portion 72. Thus, the air emitted from the blast opening 80 flows into the first ventilation flue 84 so as to be divided into the top and reverse sides of the substrate 18.

In the first ventilation flue 84, the air flowing on the top side of the substrate 18 exchanges heat with the heat pipe 66, absorbs heat from the heat pipe 66, directly absorbs the heat of the CPU 64 provided in the first ventilation flue 84 and decreases the temperature of the CPU 64.

After the temperature of the CPU 64 is decreased, the air goes through the first ventilation flue 84 and flows to the rear side of the CPU 64. After absorbing heat from the heat pipe 66 and the CPU 64, the temperature of the air is increased in connection with the absorbed heat.

The temperature of the air is increased through the passage of the first ventilation flue 84. Subsequently, the air flows into the second ventilation flue 86. After the air flows into the second ventilation flue 86, the flow of air is bent by the second side plate 52 at the left end of the housing 16 as shown with the arrow such that the air flows along the second side plate 52. Subsequently, the air flows from the second ventilation flue 86 into the third ventilation flue 88.

The third ventilation flue 88 is provided on the front side of the main portion 12. Few electronic components in which the amount of heat generation is great are provided in the second ventilation flue 86 or the third ventilation flue 88 of the main portion 12.

While the air passes through the second and third ventilation flues 86 and 88, the air is in contact with the upper and lower plates 32 and 34 of the second and third ventilation flues 86 and 88 such that the heat of the air is absorbed. Thus, the heat is absorbed by the housing 16 including the upper and lower plates 32 and 34. In this way, the temperature of the air is gradually decreased.

After the air passes through the third ventilation flue 88, the air is sucked by the fan 20 from the suction opening 78. Since the suction opening 78 is provided on each of the upper and lower surfaces of the fan 20, the air is sucked through both of the upper and lower surfaces of the fan 20. The air is transferred from the blast opening 80 of the fan 20 to the first ventilation flue 84 again through the opening portion 72.

The air is cooled while it passes through the second and third ventilation flues 86 and 88. The air with a decreased temperature is emitted to the main portion 12 and cools the CPU 64. The temperature of the air is increased by cooling the CPU 64. Subsequently, the air is cooled by the second ventilation flue 86, etc., again, and returns to the fan 20.

In the above manner, air circulates inside the main portion 12, repeating the absorption of heat from heat generators such as the CPU 64 and the diffusion of heat in the other portions. In this way, the air circulating inside the main portion 12 cools the CPU 64. Thus, it is possible to prevent the CPU 64 from overheating.

The heat generated inside the main portion 12 is dispersed by the circulating air such that the internal temperature is equalized. Thus, it is possible to prevent electronic components, etc., from overheating and retain a desired temperature range for a long time.

Further, for example, when the processing amount of the CPU 64 is increased, and the temperature of the CPU 64 is increased, the difference in temperature between the air internally circulating and the CPU 64 is large. The amount of heat transferred from the CPU 64 to the air is increased. Thus, a greater amount of heat of the CPU 64 is absorbed by the air. Subsequently, cooling is performed.

When the temperature of air is increased by the transfer of heat from the CPU 64, etc., the difference in temperature between the housing 16 and the air is large. The amount of heat transferred from the air to the housing 16 is increased. Thus, the temperature of the flow of air is decreased.

As explained above, while the fan 20 operates, air circulates inside the main portion 12 in the computer 10 of the present embodiment. The air circulating inside the main portion 12 absorbs heat from heat generators such as the CPU 64 having a temperature higher than that of the air, and decreases the temperature of the CPU 64. After absorbing heat, the temperature of the air is increased. The air with an increased temperature is in contact with the upper and lower plates 32 and 34 having a temperature lower than that of the air. In this way, the heat of the air is absorbed, and the temperature of the air is decreased. The air with a decreased temperature returns to the fan 20 and is transferred from the fan 20 to the first ventilation flue 84 again. Thus, the CPU 64 is continuously cooled.

Even when the fan 20 constantly circulates air inside the main portion 12, the efficiency of transfer of heat from the CPU 64 to air changes in the computer 10 of the present embodiment in accordance with the change in the temperature of the CPU 64. Thus, the temperature of heat generators such as the CPU 64 can be maintained in a setting range. The air volume of the fan 20 may change in accordance with the internal temperature of the main portion 12, etc.

In the present embodiment, it is possible to effectively prevent the local excessive elevation of temperature in connection with the heat generated by heat generators such as the CPU 64. When the amount of heat generated by heat generators such as the CPU 64 is appropriate, the air circulating inside the main portion 12 can sufficiently prevent the CPU 64, etc., from overheating.

In the computer 10 of the present embodiment, both the suction opening 78 and the blast opening 80 of the fan 20 provided inside the housing 16 are open inside the housing 16. Further, the suction opening 78 is connected to the blast opening 80 via the ventilation flues for circulation. Thus, even if an opening portion which communicates with outside is provided in the housing 16, the difference in pressure is small between the inside and outside of the housing 16. In this way, air is not substantially drawn from the outside into the inside of the main portion 12.

The computer 10 of the present embodiment has the following advantages in comparison with a structure in which generators such as a CPU are cooled by a sheet-like heat conductive member. For example, the sheet-like heat conductive member absorbs heat from the heat generators. The heat conductive member cools the heat generators by naturally releasing the absorbed heat to the housing or transferring the absorbed heat to the housing in contact with the heat conductive member. Thus, when the sheet-like heat conductive member is used, the air in the housing basically does not circulate. As the temperature of the heat generators such as the CPU is increased, the surrounding temperature is increased. Thus, it becomes difficult to cool the heat generators.

If a sheet-like heat conductive member is used such that the amount corresponds to the heat generation in the state of ordinary use, the cooling capacity may be insufficient at the time of maximum heat generation. However, if a heat conductive member is used such that the amount corresponds to the maximum heat generation to deal with a state where the heat generation of the CPU 64, etc., is maximum, the heat conductive member is excessive in the state of ordinary use. Thus, the weight and cost are increased, resulting in over capacity.

In the present embodiment, the fan 20 is used to circulate air, and thus, the blast from the fan 20 can forcibly move the air around the CPU 64. In this way, even the air circulating inside the housing 16 can sufficiently cool heat generators such as the CPU 64. In particular, the air circulation by the fan 20 can effectively deal with a problem that the temperature of individual electronic components such as the CPU 64 is locally increased rather than the overheating of the computer 10 as a whole. When the fan 20 is used, the cooling efficiency is higher than that when a heat conductive member is used. The size and weight of the computer 10 can be reduced when comparison is made based on the same cooling capacity.

In the present embodiment, the fan 20 and the partition walls are provided simply inside the housing 16. Thus, the computer 10 can be composed in an assembling process similar to that of the conventional technique. The trouble or cost for manufacturing the computer 10 is not substantially increased. The computer 10 can effectively prevent the internal temperature from increasing while the thin and light structure in the conventional technique is maintained.

The computer 10 does not comprise an opening portion for absorbing or emitting cooling air from or to the main portion 12. Thus, the noise generated inside the main portion 12, for example, by the fan 20, is not released to outside. In this way, calmness can be maintained. In the computer 10, cooling air does not come in or out of the main portion 12. Thus, no wind noise is generated near the absorption or emission opening. In this manner, calmness can be maintained.

In the computer 10, external air is not introduced into the main portion 12. Thus, the inside of the main portion 12 does not get dirty by the dust contained in external air. In the computer 10, generators such as the CPU 64 are forcibly cooled by the blast from the fan 20. In this way, thermal reliability is improved.

Recently, electronic components are designed such that the amount of heat generated by the individual electronic components is less. Therefore, the electronic components are sufficiently cooled by circulating air inside the main portion 12. Even if the amount of heat generated by the heat generators is maximum, the fan 20 forcibly forms the flow of air. Thus, overheat can be appropriately dealt with in comparison with when a heat conductive member such as a radiation sheet which statically performs cooling is used. When both the fan 20 and a sheet-like heat conductive member are used, the effect is stronger.

In the above embodiment, the substrate 18 is spaced from the bottom plate 40. However, the substrate 18 may be directly attached to the bottom plate 40. In the above embodiment, the other end of the heat pipe 66 is provided near the suction opening 78 of the fan 20. However, the other end of the heat pipe 66 may be provided at a different position. In the above embodiment, air is transferred from the fan 20 to the CPU 64. However, the direction of the flow of air is not limited to this example, and may be opposite to that of the example.

In the above embodiment, the fan 20 is a centrifugal fan. However, the system of the fan is not limited to this example. A heat conductive member which cools the air passing through the second ventilation flue 86 and the third ventilation flue 88, etc., may be provided in the second ventilation flue 86 and the third ventilation flue 88. An opening portion which penetrates the housing 16 such that the inside communicates with the outside may be provided near the fan 20. An openable cover by which the opening portion is open and closed may be provided. The cooling capacity can be enhanced by opening the openable cover and introducing external air into the inside of the main portion 12 as necessary.

Heat generators are not limited to the CPU 64 provided on the substrate 18. Heat generators may not be provided on the substrate 18. Heat generators and heat conductive members are not limited to the attachment state of the above embodiment. For example, a heat conductive member may be provided at a position in contact with the flow of air such that a heat generator is cooled.

The above embodiment is explained using a clamshell personal computer as an example. However, the present embodiment may be a computer which can be used by separating the display portion 14 from the main portion 12, a tablet electronic device, or another common electronic device comprising a heat generator.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing having an internal space;
a fan provided inside the housing;
a ventilation flue provided inside the housing to circulate air in the internal space, the air emitted from the fan and to guide the air to a suction opening of the fan; and
a heat generator provided in a path of a flow of the air.

2. The apparatus of claim 1, wherein
the ventilation flue is formed by a partition wall provided inside the housing to divide the internal space.

3. The apparatus of claim 2, wherein
the partition wall is provided between the fan and the heat generator, such that an emission opening for emitting the air from the fan is provided on one side of the internal space divided by the partition wall and the suction opening is provided on the other side of the internal space divided by the partial wall, such that a circulation path is formed in the internal space.

4. The apparatus of claim 3,
further comprising a substrate provided inside the housing;
wherein the heat generator is attached to a surface of the substrate and the flow of the air is formed along the surface of the substrate.

5. The apparatus of claim 4, wherein
one end of a heat conductive member which transfers heat is attached to the heat generator and the other end of the heat conductive member is provided near at least one of the suction opening and the emission opening of the fan.

6. The apparatus of claim 4, wherein
the housing further includes a lower plate and an upper plate attached to the lower plate,
the heat generator is an electronic component attached to the substrate provided at a predetermined distance from the lower plate of the housing and
the ventilation flue is provided on both top and reverse sides of the substrate.

7. The apparatus of claim 6, wherein
the electronic apparatus is a computer and the heat generator is an electronic component of the computer.

8. The apparatus of claim 7, wherein
the electronic component is a CPU.

9. The apparatus of claim 8, wherein
the heat conductive member is a heat pipe.
